(19) United States
(12) Patent Application Publication
(10) Pub. No.: US 2021/0020501 A1
(43) Pub. Date: Jan. 21, 2021

(54) SEMICONDUCTOR DEVICE AND MANUFACTURING METHOD THEREOF

(71) Applicant: Kioxia Corporation, Minato-ku (JP)

(72) Inventors: Takanobu ONO, Kuwana (JP); lppei KUME, Yokkaichi (JP)

(73) Assignee: Kioxia Corporation, Minato-ku (JP)

(21) Appl. No.: 16/806,040

(22) Filed: Mar. 2, 2020

(30) Foreign Application Priority Data
Jul. 16, 2019 (JP) 2019-131302
Dec. 12, 2019 (JP) 2019-224855

(51) Int. Cl. H01L 21/768; H01L 21/268; H01L 21/02; H01L 21/8238; H01L 21/8239

(52) U.S. Cl. CPC H01L 21/76834; H01L 21/268; H01L 21/02164; H01L 21/8238; H01L 21/8239; H01L 21/0217

(57) ABSTRACT

A semiconductor device according to an embodiment comprises a semiconductor substrate and a semiconductor element provided on the semiconductor substrate. A first insulation film is configured to cover the semiconductor element. A first sidewall film is provided on a side part of the first insulation film, of which an absorption coefficient for ultraviolet light is larger than that of the first insulation film.

### CROSS REFERENCE TO RELATED APPLICATIONS

This application is based upon and claims the benefit of priority from the prior Japanese Patent Applications No. 2019-131302, filed on Jul. 16, 2019 and No. 2019-224855, filed on Dec. 12, 2019, the entire contents of which are incorporated herein by reference.

### FIELD

The embodiments of the present invention relate to a semiconductor device and manufacturing method thereof.

### BACKGROUND

In a semiconductor memory that includes a three-dimensional memory cell array in which memory cells are three-dimensionally arranged, delamination at an interface or a bonding surface in a laminated structure may occur because of dicing. Delamination at the interface or the bonding surface in the laminated structure significantly occurs in blade dicing, and also occurs in a dicing method that uses laser, such as laser dicing.

### BRIEF DESCRIPTION OF THE DRAWINGS

FIG. 1 is a cross-sectional view illustrating a configuration example of a semiconductor device according to a first embodiment;

FIG. 2A is a plan view illustrating a configuration example of a semiconductor device according to the first embodiment;

FIG. 2B is a plan view illustrating another configuration example of a semiconductor chip according to the first embodiment;

FIGS. 3 to 19 are cross-sectional views illustrating a manufacturing method of a semiconductor device according to the first embodiment;

FIG. 20 is a cross-sectional view illustrating a configuration example of a semiconductor device according to a second embodiment;

FIG. 21 is a cross-sectional view illustrating a configuration example of a semiconductor device according to a third embodiment;

FIG. 22 is a cross-sectional view illustrating a configuration example of a semiconductor device according to a fourth embodiment;

FIG. 23 is a cross-sectional view illustrating a configuration example of a semiconductor device according to a fifth embodiment;

FIG. 24 is a plan view illustrating a configuration example of a semiconductor device according to a seventh embodiment;

FIG. 25 illustrates a cross-section along a line 25-25 in FIG. 24;

FIG. 26 is a cross-sectional view illustrating a configuration example of a semiconductor device according to an eighth embodiment;

FIG. 27 is a cross-sectional view illustrating a manufacturing method of a semiconductor device according to a ninth embodiment; and

FIG. 28 is a cross-sectional view illustrating a manufacturing method of a semiconductor device according to a tenth embodiment.

### DETAILED DESCRIPTION

Embodiments will now be explained with reference to the accompanying drawings. The present invention is not limited to the embodiments. In the embodiments, “an upper direction” or “a lower direction” refers to a relative direction when a direction perpendicular to a surface of a semiconductor substrate on which semiconductor elements are provided is assumed as “an upper direction”. Therefore, the term “upper direction” or “lower direction” occasionally differs from an upper direction or a lower direction based on a gravitational acceleration direction. In the present specification and the drawings, elements identical to those described in the foregoing drawings are denoted by like reference characters and detailed explanations thereof are omitted as appropriate.

A semiconductor device according to an embodiment comprises a semiconductor substrate and a semiconductor element provided on the semiconductor substrate. A first insulation film is configured to cover the semiconductor element. A first sidewall film is provided on a side part of the first insulation film, of which an absorption coefficient for ultraviolet light is larger than that of the first insulation film.

### First Embodiment

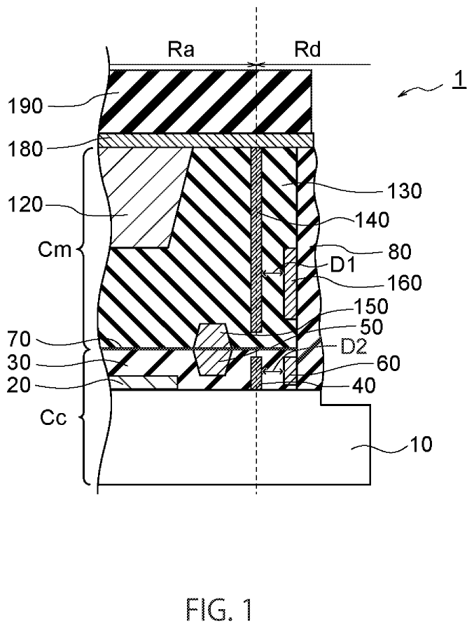

FIG. 1 is a cross-sectional view illustrating a configuration example of a semiconductor device according to a first embodiment. A semiconductor device 1 is, for example, a semiconductor chip of a NAND flash memory, which includes a three-dimensional memory cell array in which memory cells are arranged three-dimensionally. The present embodiment is not limited to a NAND flash memory and can also be applied to other semiconductor devices.

In the present embodiment, the semiconductor device 1 is a semiconductor chip obtained by bonding a controller chip Cc and a memory chip Cm to each other. FIG. 1 illustrates an end of the chip of the NAND flash memory and illustrates a boundary portion between an element-formation region Ra and a dicing region Rd.

The controller chip Cc includes a semiconductor substrate 10, a semiconductor element 20, a first interlayer dielectric film 30 as a first insulation film, a seal ring 40, a bonding pad 50, and a first sidewall film 60.

The semiconductor substrate 10 includes the element-formation region Ra for formation of the semiconductor element 20 and the dicing region Rd used for dicing of the semiconductor substrate 10 into semiconductor chips. The element-formation region Ra occupies most of the semiconductor substrate 10. The dicing region Rd is provided in an outer edge of the element-formation region Ra. Because the dicing region Rd is cut in a dicing process, the dicing region Rd is not required to be left in the outer edge of the element-formation region Ra. However, generally, the dicing region Rd is slightly left outside the element-formation region Ra in many cases. The semiconductor substrate 10 may be a silicon substrate, for example.

The semiconductor element 20 may be a CMOS (Complementary Metal Oxide Semiconductor) that configures a controller for the memory chip Cm, for example. The semiconductor element 20 is provided in the element-formation region Ra but is not provided in the dicing region Rd.

The first interlayer dielectric film 30 covers the element-formation region Ra and the dicing region Rd outside the element-formation region Ra. The first interlayer dielectric film 30 covers and protects the semiconductor element 20. For example, the first interlayer dielectric film 30 may include a silicon oxide film such as TEOS (TetraEthoxySilane).

The seal ring 40 is provided in the first interlayer dielectric film 30. The seal ring 40 extends from a top surface of the semiconductor substrate 10 to the vicinity of a top surface of the first interlayer dielectric film 30. The seal ring 40 is grounded and allows electric charges from outside to be released to the ground (not illustrated), for example. The seal ring 40 also suppresses damage such as delamination or a crack, or moisture from outside from reaching the semiconductor element 20, for example. Conductive metal such as tungsten is used for the seal ring 40, for example.

The bonding pad 50 as a conductor is provided in a surface of the first interlayer dielectric film 30 and, when the memory chip Cm and the controller chip Cc are bonded to each other, the bonding pad 50 adheres to a bonding pad 150 as a conductor on the memory chip Cm side. Copper or a metal material containing copper is used for the bonding pad 50, for example.

The first sidewall film 60 served as a light absorption film is provided on a side part of the first interlayer dielectric film 30 at an end of the dicing region Rd of the semiconductor device 1. The first sidewall film 60 may be exposed on a side surface of the first interlayer dielectric film 30. The first sidewall film 60 absorbs laser light used in a dicing process and generates heat, thereby melting the first interlayer dielectric film 30 therearound. The first sidewall film 60 itself also melts by absorbing the laser light. Therefore, the first sidewall film 60 is formed of a material of which an absorption coefficient for the laser light is larger than that of the first interlayer dielectric film 30 (for example, a silicon oxide film). For example, the first sidewall film 60 is preferably formed of a material having an absorption coefficient of 0.001 or more for a wavelength of 400 nm or less (ultraviolet light) (preferably, about 355 nm). In more detail, the first sidewall film 60 contains a silicon nitride film or metal. More preferably, the first sidewall film 60 contains at least one of materials of tungsten, titanium, and aluminum.

The first sidewall film 60 absorbs the laser light and becomes a heat source for melting the first interlayer dielectric film 30. The melted first interlayer dielectric film 30 covers an outer side surface of the first sidewall film 60 to become a second sidewall film 80 as a second sidewall film. Therefore, the composition of the second sidewall film 80 contains the same material as the first interlayer dielectric film 30. Further, the second sidewall film 80 may contain a part of the composition of the melted first sidewall film 60. The first sidewall film 60 itself also melts by absorbing the laser light, thereby adhering to the side surface of the first interlayer dielectric film 30. In this manner, the second sidewall film 80 and/or the first sidewall film 60 melt/melts by the laser light once and, when being cooled, are/is welded to the side surface of the first interlayer dielectric film 30. Accordingly, the second sidewall film 80 and/or the first sidewall film 60 adhere/adheres to the side surface of the first interlayer dielectric film 30 and protect/protects it. As a result, delamination or a crack in the first interlayer dielectric film 30 can be suppressed.

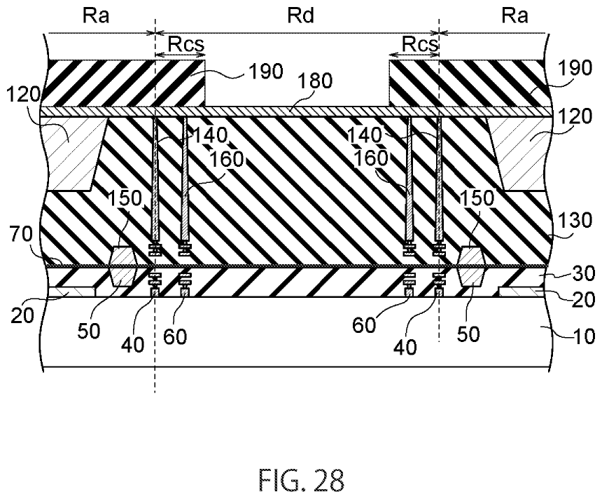

In the first embodiment, the first sidewall film 60 may have a configuration different from that of the seal ring 40 as illustrated in FIG. 1. However, the first sidewall film 60 may have substantially the same configuration as that of the seal ring 40. In this case, the first sidewall film 60 may be formed by the same process as the seal ring 40 in the same depth (height) region as the seal ring 40, for example. For example, FIG. 28 illustrates a mode in which the first sidewall film 60 has substantially the same configuration as the seal ring 40.

The memory chip Cm includes a memory cell array 120, a second interlayer dielectric film 130 as the first insulation film, a seal ring 140, the bonding pad 150, and a first sidewall film 160. The memory chip Cm is bonded to the controller chip Cc at a bonding surface 70 as an interface.

The memory cell array 120 is formed in the element-formation region Ra above the semiconductor element 20. The memory cell array 120 is electrically connected to the semiconductor element 20 via a wire, a contact, a pad, and the like (not illustrated), and undergoes control from the semiconductor element 20 as a controller. The memory cell array 120 is a three-dimensional memory cell array in which a number of memory cells are arranged three-dimensionally, for example.

The second interlayer dielectric film 130 covers the element-formation region Ra and the dicing region Rd. The second interlayer dielectric film 130 covers and protects the memory cell array 120. The second interlayer dielectric film 130 is preferably formed of the same material as the first interlayer dielectric film 30, and may be formed by a silicon oxide film such as TEOS, for example.

The seal ring 140 is provided in the second interlayer dielectric film 130. The seal ring 140 is grounded and allows electric charges from outside to be released to the ground (not illustrated), for example. The seal ring 140 also suppresses damage, such as delamination or a crack, or moisture from outside from reaching the memory cell array 120, for example. The seal ring 140 is preferably formed of the same material as the seal ring 40, and, for example, may contain conductive metal such as tungsten.

The bonding pad 150 is provided on a surface of the second interlayer dielectric film 130 and, when the memory chip Cm and the controller chip Cc are bonded to each other, the bonding pad 150 adheres to the bonding pad 50 on the controller chip Cc side. That is, the bonding pads 50 and 150 are provided at positions corresponding to each other near the boundary between the element-formation region Ra and the dicing region Rd. The bonding pad 150 is preferably formed of the same material as the bonding pad 50, and copper or a metal material containing copper is used, for example. The bonding pad 50 and the bonding pad 150 are connected directly or contacted to each other via the bonding surface 70 and are integrated with each other. That is, a conductor having the bonding pad 50 and the bonding pad 150 integrated with each other cross the bonding surface 70 (is connected and continuous) vertically. The bonding pad 50 and 150 are electrically connected to semiconductor circuits included in the memory chip Cm and the controller chip Cc through interconnects which are not drawn.

The first sidewall film 160 served as a light absorption film is provided on a side surface of the second interlayer dielectric film 130 at an end of the dicing region Rd of the semiconductor device 1. The first sidewall film 160 may be exposed on a side surface of the second interlayer dielectric film 130. The first sidewall film 160 absorbs laser light used in a dicing process and generates heat, thereby melting the second interlayer dielectric film 130 therearound. The first sidewall film 160 itself also melts by absorbing the laser light. Therefore, the first sidewall film 160 is formed of a material of which an absorption coefficient for the laser light is larger than that of the second interlayer dielectric film 130 (for example, a silicon oxide film). The first sidewall film 160 is preferably formed of the same material as the first sidewall film 60, and is preferably formed of a material having an absorption coefficient of 0.001 or more for light of a wavelength of 400 nm or less (more preferably, about 355 nm). In more detail, the first sidewall film 160 contains either silicon nitride or metal. More preferably, the first sidewall film 60 contains at least one of tungsten, titanium, and aluminum.

The first sidewall film 160 absorbs the laser light and becomes a heat source for melting the second interlayer dielectric film 130. The melted second interlayer dielectric film 130 covers an outer side surface of the first sidewall film 160 to become the second sidewall film 80. Therefore, the composition of the second sidewall film 80 contains the same material as the second interlayer dielectric film 130. Further, the second sidewall film 80 may contain a part of the composition of the melted first sidewall film 160.

The first sidewall film 160 itself also melts by absorbing the laser light, thereby adhering to the side surface of the second interlayer dielectric film 130. In this manner, the second sidewall film 80 and/or the first sidewall film 160 melt/melts by the laser light once and, when being cooled, the second sidewall film 80 and/or the first sidewall film 160 are/is welded to the side surface of the second interlayer dielectric film 130. Accordingly, the second sidewall film 80 and/or the first sidewall film 160 adhere/adheres to the side surface of the second interlayer dielectric film 130 and protect/projects it. As a result, delamination or a crack in the second interlayer dielectric film 130 can be suppressed.

In the first embodiment, the first sidewall film 160 has a configuration different from the seal ring 140, as illustrated in FIG. 1. However, the first sidewall film 160 may have substantially the same configuration as the seal ring 140. In this case, the first sidewall film 160 may be formed by the same process as the seal ring 140 in the same depth (height) region as the seal ring 140, for example. For example, FIG. 28 illustrates a mode in which the first sidewall film 160 has substantially the same configuration as the seal ring 140.

On the side surfaces of the first interlayer dielectric film 30 and the second interlayer dielectric film 130, the second sidewall film 80 is provided outside the first sidewall films 60 and 160 to cover the side surfaces of the first interlayer dielectric film 30, the second interlayer dielectric film 130, and the first sidewall films 60 and 160. The second sidewall film 80 is a film obtained by melting the first interlayer dielectric film 30 and the second interlayer dielectric film 130 and then being welded again, and includes a silicon oxide film. The second sidewall film 80 contains the same material as the first interlayer dielectric film 30 and the second interlayer dielectric film 130. Further, the second sidewall film 80 may include a part of the first sidewall films 60 and 160.

The composition of the second sidewall film 80 may be close to that of the first interlayer dielectric film 30 on the side surface of the first interlayer dielectric film 30 and be close to that of the second interlayer dielectric film 130 on the side surface of the second interlayer dielectric film 130. Therefore, the composition of the second sidewall film 80 does not need to be uniform along a direction perpendicular to a surface of the semiconductor substrate 10.

The first interlayer dielectric film 30 and the second interlayer dielectric film 130 are melted by using the first sidewall films 60 and 160 that absorb laser light as heat sources, and flow to cover side surfaces of the first sidewall films 60 and 160 and the side surfaces of the first interlayer dielectric film 30 and the second interlayer dielectric film 130. At this time, the first interlayer dielectric film 30 and the second interlayer dielectric film 130 that have been melted flow to cover also an end of the bonding surface 70. Thereafter, the first interlayer dielectric film 30 and the second interlayer dielectric film 130 are cooled to solidify, thereby becoming the second sidewall film 80 that covers the side surfaces of the first sidewall films 60 and 160, the side surfaces of the first interlayer dielectric film 30 and the second interlayer dielectric film 130, and the end of the bonding surface 70.

Alternatively, a mixture of the first sidewall film 60 or 160 and the first interlayer dielectric film 30 or the second interlayer dielectric film 130 may cover the end of the bonding surface 70.

A metal film 180 is provided on the second interlayer dielectric film 130, the seal ring 140, and the memory cell array 120 and functions as a wire. Conductive metal, such as copper, aluminum, or titanium is used for the metal film 180, for example. Further, a protection film 190 is provided on the metal film 180 and protects the memory cell array 120, the semiconductor element 20, and the like. An insulating film, such as a polyimide film, is used as the protection film 190.

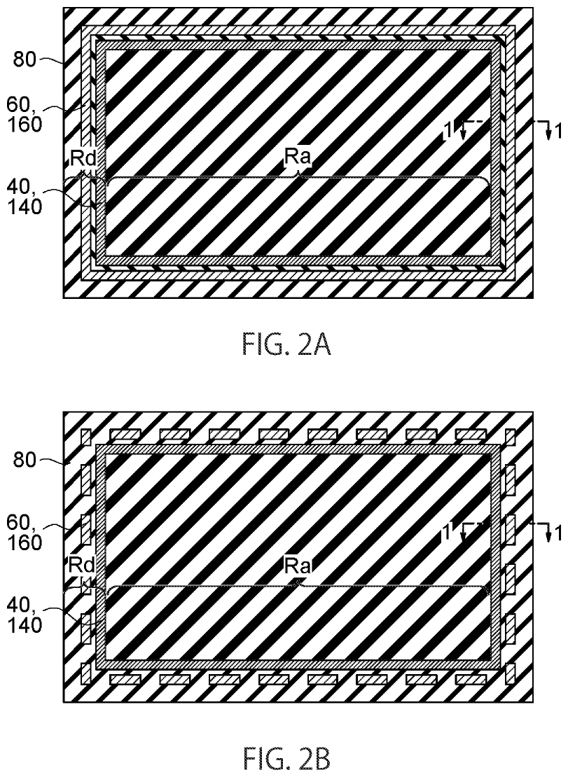

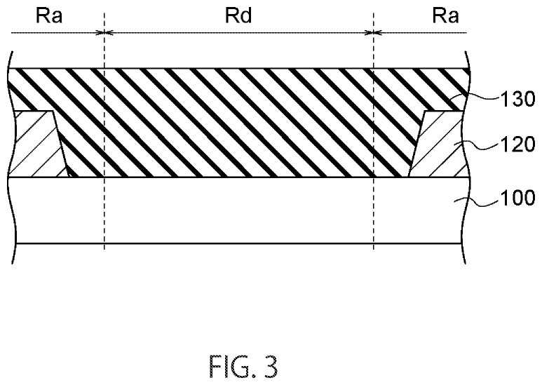

FIG. 2A is a plan view illustrating a configuration example of a semiconductor device according to the first embodiment. FIG. 1 corresponds to a cross-section along a line 1-1 in FIG. 2A.

In the present embodiment, the seal rings 40 and 140 are provided continuously in the entire surrounding area of the element-formation region Ra to surround it. The first sidewall films 60 and 160 are continuously provided outside the seal rings 40 and 140 in the entire surrounding area of the element-formation region Ra and the seal rings 40 and 140 to surround them. The second sidewall film 80 is continuously provided outside the first sidewall films 60 and 160 in the entire surrounding region of the element-formation region Ra, the seal rings 40 and 140, and the first sidewall films 60 and 160 to surround them. In this manner, the second sidewall film 80 and the first sidewall films 60 and 160 may be continuously provided in the dicing region Rd. Further, even if the second sidewall film 80 and the first sidewall films 60 and 160 are partly removed in a dicing process, there is no problem as long as there is no delamination or a crack generated.

FIG. 2B is a plan view illustrating another configuration example of a semiconductor chip according to the first embodiment. FIG. 1 corresponds to a cross-section along a line 1-1 in FIG. 2B. This configuration example is identical to that of FIG. 2A in that the seal rings 40 and 140 are continuously provided to surround the element-formation region Ra in its entire surrounding area. Meanwhile, the first sidewall films 60 and 160 are provided intermittently (in a broken-line form) outside the seal rings 40 and 140 in the surrounding area of the element-formation region Ra and the seal rings 40 and 140. The second sidewall film 80 is continuously or intermittently provided outside the first sidewall films 60 and 160 in the surrounding region of the element-formation region Ra, the seal rings 40 and 140, and the first sidewall films 60 and 160. In this manner, the second sidewall film 80 and the first sidewall films 60 and 160 may be discontinuous in a planar layout of the dicing region Rd.

As described above, according to the first embodiment, the first sidewall films 60 and 160 are provided on side surfaces of the first interlayer dielectric film 30 and the second interlayer dielectric film 130, respectively, at an end of the dicing region Rd. The first sidewall films 60 and 160 are formed of materials that are larger in an absorption coefficient for laser light used in a dicing process than the first interlayer dielectric film 30 and the second interlayer dielectric film 130 (for example, a silicon oxide film), respectively. For example, the first sidewall films 60 and 160 have an absorption coefficient of 0.001 or more for laser light having a wavelength of about 355 nm that is ultraviolet light. Any of silicon nitride, tungsten, titanium, and aluminum is used for the first sidewall films 60 and 160, for example. Accordingly, the first sidewall films 60 and 160 absorb laser light more than the first interlayer dielectric film 30 and the second interlayer dielectric film 130 in the dicing process and serve as heat sources, thereby melting the first interlayer dielectric film 30 and the second interlayer dielectric film 130. Thus, the materials of the first interlayer dielectric film 30 and the second interlayer dielectric film 130 are welded to side surfaces of the first interlayer dielectric film 30 and the second interlayer dielectric film 130 and side surfaces of the first sidewall films 60 and 160 as the second sidewall film 80. Further, the first sidewall films 60 and 160 themselves also melt by absorbing the laser light, thereby being welded to the side surfaces of the first interlayer dielectric film 30 and the second interlayer dielectric film 130. Accordingly, the second sidewall film 80 and the first sidewall films 60 and 160 can suppress delamination or a crack of the first interlayer dielectric film 30 and the second interlayer dielectric film 130 from ends thereof towards the element-formation region Ra. That is, the first sidewall films 60 and 160 may have function of delamination suppression films suppressing the delamination of the interlayer dielectric films 30 and 130.

Further, the second sidewall film 80 also covers an end of the bonding surface 70 and is welded to it. Accordingly, it is possible to suppress delamination between the memory chip Cm and the controller chip Cc at the bonding surface 70.

In the first embodiment, a CMOS is provided as the semiconductor element 20 on the semiconductor substrate 10, and the memory cell array 120 is provided above the CMOS.

However, this arrangement may be turned upside down. That is, the memory cell array 120 may be provided as a semiconductor element on the semiconductor substrate 10, and the CMOS may be provided above the memory cell array 120.

Next, a manufacturing method of the semiconductor device 1 is described.

FIGS. 3 to 19 are cross-sectional views illustrating a manufacturing method of a semiconductor device according to the first embodiment. In the following manufacturing method, material films (for example, the first interlayer dielectric film 30 and the second interlayer dielectric film 130) on the semiconductor substrate 10 in the dicing region Rd are partly removed by laser light, and thereafter blade dicing is performed. This dicing method is different from laser dicing that uses cleavage of the semiconductor substrate 10 and a semiconductor substrate 100 (Stealth dicing (registered trademark)).

### (Formation Process of Memory Chip Cm)

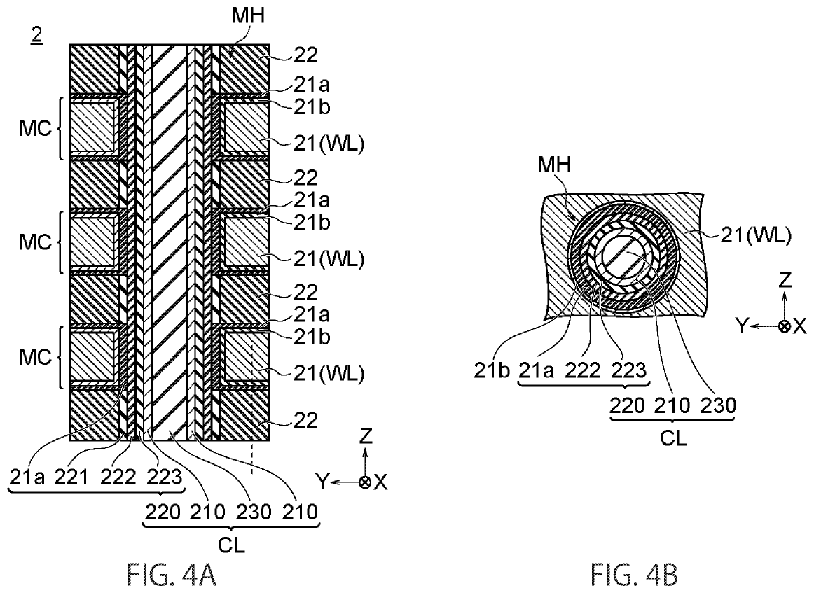

First, as illustrated in FIG. 3, the memory cell array 120 is formed on the semiconductor substrate 100 as a second semiconductor wafer. The memory cell array 120 has a laminated structure of conductive layers 21 and insulation layers 22 as illustrated in FIG. 4A, for example. The conductive layers 21 may be formed of tungsten or polysilicon, for example. The insulation layers 22 may be formed of a silicon oxide film, for example. Although not illustrated in FIG. 3, the memory cell array 120 includes a laminated structure 2 that includes a number of memory holes MH illustrated in FIGS. 4A and 4B. FIG. 3 illustrates a part of a cross-section of the dicing region Rd and the two element-formation regions Ra located on both sides of the dicing region Rd.

FIG. 4A is a cross-sectional view illustrating a configuration example of the memory cell array 120. The configuration of the memory cell array 120 is briefly described here.

The laminated structure 2 has the conductive layers 21 and the insulation layers 22 alternately arranged along the Z-axis direction. Conductive metal, for example, tungsten is used for the conductive layers 21. Silicon oxide is used for the insulation layers 22, for example. Each insulation layer 22 is provided between the conductive layers 21 adjacent to each other in the Z-axis direction to insulate them from each other.

The memory holes MH penetrate through the laminated structure 2 from a top end of the laminated structure 2 along the Z-axis direction. A plurality of first column portions CL each include a semiconductor body 210, a memory film 220, and a core layer 230. The memory film 220 has a charge trapping portion between the semiconductor body 210 and the conductive layer 21.

As illustrated in FIG. 4B, the shape of the memory holes MH in the X-Y plane is, for example, circular or elliptical. A block insulation film 21a that configures a part of the memory film 220 may be provided between the conductive layer 21 and the insulation layer 22. The block insulation film 21a is, for example, a silicon oxide film or a metal oxide film (such as an aluminum oxide film). A barrier film 21b may be provided between the conductive layer 21 and the insulation layer 22, and between the conductive layer 21 and the memory film 220. In a case where the conductive layer 21 is made of tungsten, the barrier film 21b is preferably a laminated film of titanium nitride and titanium, for example. The block insulation film 21a suppresses back tunneling of electric charges from the conductive layer 21 toward the memory film 220. The barrier film 21b improves adhesion between the conductive layer 21 and the block insulation film 21a.

The semiconductor body 210 is made of, for example, polysilicon. The semiconductor body 210 is made of, for example, undoped polysilicon. The semiconductor body 210 serves as a channel of each of a drain-side selection transistor STD, the memory cell MC, and a source-side selection transistor STS.

A portion of the memory film 220, which is other than the block insulation film 21a, is provided between an inner wall of the memory hole MH and the semiconductor body 210. The memory cells MC each have a storage region between the semiconductor body 210 and the conductive layer 21 that serves as a word line WL, and are stacked in the Z-axis direction. The memory film 220 includes a cover insulation film 221, a charge trapping film 222, and a tunnel insulation film 223, for example. The semiconductor body 210, the charge trapping film 222, and the tunnel insulation film 223 each extend in the Z-axis direction.

The cover insulation film 221 is provided between the insulation layer 22 and the charge trapping film 222. The cover insulation film 221 contains silicon oxide, for example. The cover insulation film 221 protects the charge trapping film 222 from being etched when a sacrificial film (not illustrated) is replaced with the conductive layer 21 (in a replacing process). The cover insulation film 221 may be removed from between the conductive layer 21 and the memory film 220 in the replacing process. In this case, as illustrated in FIGS. 4A and 4B, the block insulation film 21a is provided between the conductive layer 21 and the charge trapping film 222, for example.

The charge trapping film 222 is provided between the block insulation film 21a and the cover insulation film 221, and the tunnel insulation film 223. The charge trapping film 222 contains silicon nitride, for example, and has therein a trap site at which an electric charge is trapped. A portion of the charge trapping film 222, which is sandwiched between the conductive layer 21 serving as the word line WL and the semiconductor body 210, configures the storage region of the memory cell MC as a charge trapping portion. A threshold voltage of the memory cell MC is changed depending on the presence of an electric charge in the charge trapping portion or the amount of electric charges trapped in the charge trapping portion. Accordingly, the memory cell MC can retain information.

The tunnel insulation film 223 is provided between the semiconductor body 210 and the charge trapping film 222. The tunnel insulation film 223 contains silicon oxide, or silicon oxide and silicon nitride, for example. The tunnel insulation film 223 is a potential barrier between the semiconductor body 210 and the charge trapping film 222. For example, electrons and holes each pass (tunnel) through the potential barrier by the tunnel insulation film 223, when the electrons are injected from the semiconductor body 210 to the charge trapping portion (a write operation) and when the holes are injected from the semiconductor body 210 to the charge trapping portion (an erase operation).

The core layer 230 is embedded in an inner space of the semiconductor body 210 that is tubular. The core layer 230 contains silicon oxide, for example, and is insulating.

Referring back to FIG. 3, the description of the manufacturing method according to the present embodiment is continued. Next, the second interlayer dielectric film 130 is formed on the memory cell array 120 and the semiconductor substrate 100. The second interlayer dielectric film 130 is formed to cover and protect the memory cell array 120. The second interlayer dielectric film 130 may be, for example, a silicon oxide film such as TEOS. Further, the second interlayer dielectric film 130 may include a laminated film in which a sacrificial film when the word line WL of the memory cell array 120 is formed and the insulation layer 22 are repeatedly stacked. Here, the sacrificial film may be a silicon nitride film. The laminated film is formed up to the vicinity of the top of the memory cell array 120.

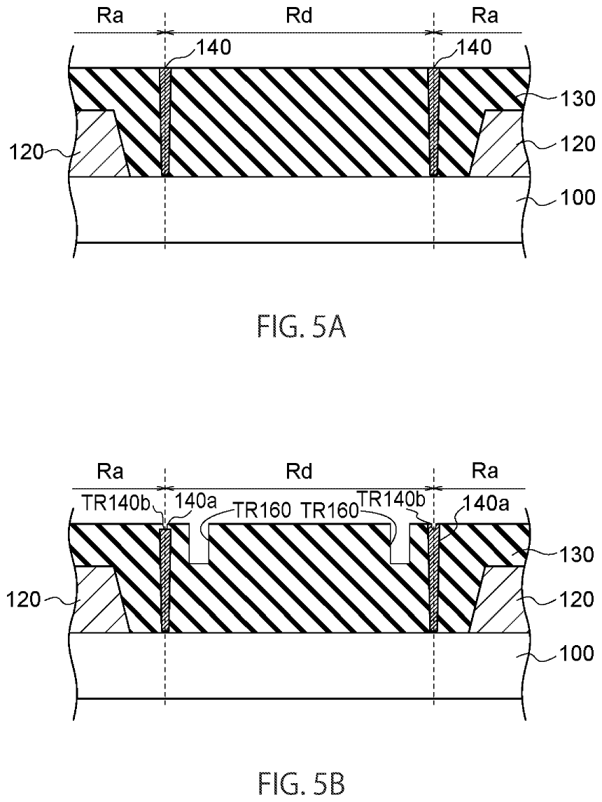

Next, a seal ring portion 140a that penetrates through the second interlayer dielectric film 130 is formed, as illustrated in FIG. 5A. The seal ring portion 140a is provided in the entire surrounding area of the element-formation region Ra to surround each element-formation region Ra. Therefore, two seal ring portions 140a appear in the cross-section of the dicing region Rd. The seal ring portion 140a is a portion of the seal ring 140 and, for example, may be formed of conductive metal such as tungsten.

Next, the material of the second interlayer dielectric film 130 is deposited thinly, and thereafter a trench TR160 is formed in the second interlayer dielectric film 130 by lithography and etching, as illustrated in FIG. 5B. The trench TR160 is formed in the entire surrounding area of the element-formation region Ra along an outer side surface of the seal ring portion 140a. The trench TR160 is provided between the two seal ring portions 140a adjacent to each other in the dicing region Rd. Each trench TR160 is formed in the vicinity of the seal ring portion 140a.

Further, simultaneously with formation of the trench TR160, a trench TR140b is formed on the seal ring portion 140a. The trench TR140b is also provided in the entire surrounding area of the element-formation region Ra along the seal ring portion 140a.

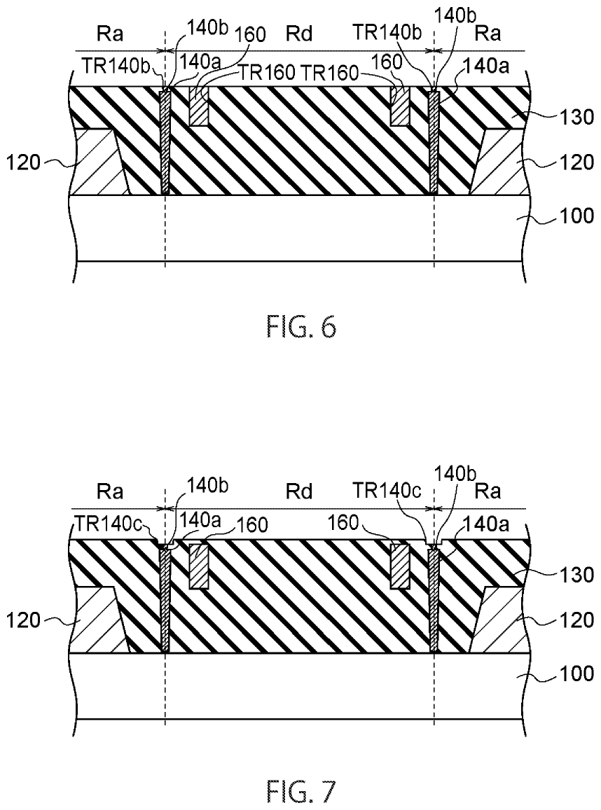

Subsequently, a conductive material is filled into the trench TR160 and the trench TR140b, as illustrated in FIG. 6. The conductive material may be a metal material, such as tungsten, titanium, or aluminum, that can form the first sidewall film 160. Accordingly, the first sidewall film 160 is formed in the trench TR160, and a seal ring portion 140b is formed in the trench TR140b. Here, the first sidewall film 160 before being subjected to a dicing process described later is referred to as a first embedding film.

In a case of using a silicon nitride film as the material of the first sidewall film 160, the trench TR160 and the first sidewall film 160 are formed separately from the trench TR140b and the seal ring portion 140b. In this case, any conductive material can be used for the seal ring portion 140b.

Next, as illustrated in FIG. 7, the material of the second interlayer dielectric film 130 is deposited thinly, and thereafter a trench TR140c is formed in the second interlayer dielectric film 130 above the seal ring portion 140b by lithography and etching. The trench TR140c is formed in the entire surrounding area of the element-formation region Ra along the seal ring portion 140a.

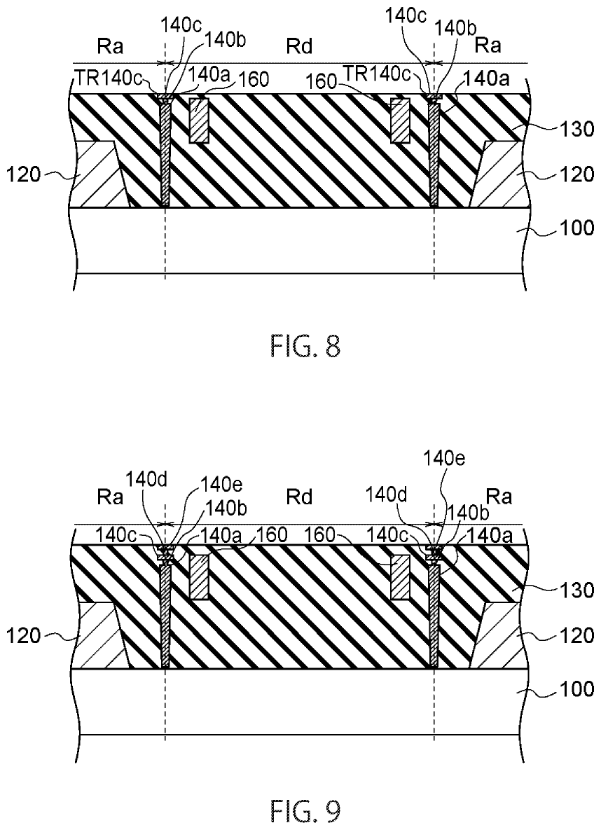

Subsequently, a conductive material is filled into the trench TR140c, as illustrated in FIG. 8. The conductive material may be the same as the material of the seal ring portion 140b. Accordingly, a seal ring portion 140c is formed in the trench TR140c.

Similarly, deposition of the material of the second interlayer dielectric film 130, formation of a trench, and filling of the trench with a conductive material are repeated to form seal ring portions 140d and 140e in the second interlayer dielectric film 130, as illustrated in FIG. 9. The seal ring portions 140a to 140e can be formed simultaneously in a process of forming the memory cell array 120 or a wiring layer above the memory cell array 120. The seal ring portions 140a to 140e are referred to as the seal ring 140 in the following descriptions. The seal ring 140 in FIG. 1 is illustrated by simplifying the seal ring 140 illustrated in FIG. 9. The trench TR160 may be formed by the same process as the seal ring 140 and have the same configuration as the seal ring 140.

Next, the material of the second interlayer dielectric film 130 is further deposited, and thereafter the bonding pad 150 is formed in the second interlayer dielectric film 130. The bonding pad 150 is formed between the seal ring 140 and the memory cell array 120 in the element-formation region Ra. A surface of the bonding pad 150 is substantially flush with a surface of the second interlayer dielectric film 130 and is exposed from the second interlayer dielectric film 130. In this manner, the memory cell array 120 is formed on the semiconductor substrate 100.

### (Formation Process of Controller Chip Cc)

Next, a formation method of the controller chip Cc is described.

First, as illustrated in FIG. 11, the semiconductor element 20 is formed on the semiconductor substrate 10 as a first semiconductor wafer. The semiconductor element 20 is formed in each of the element-formation regions Ra. The semiconductor element 20 is a control circuit configured by a CMOS, for example, and is a circuit that controls the memory cell array 120. FIG. 11 illustrates a part of a cross-section of the dicing region Rd and the two element-formation regions Ra located on both sides of the dicing region Rd.

Next, the first interlayer dielectric film 30 is formed on the semiconductor element 20 and the semiconductor substrate 10. The first interlayer dielectric film 30 as the first insulation film is formed on the element-formation regions Ra and the dicing region Rd and covers and protects the semiconductor element 20. The first interlayer dielectric film 30 may include a silicon oxide film such as TEOS, for example.

Next, a seal ring portion 40a that penetrates through the first interlayer dielectric film 30 is formed. The seal ring portion 40a is provided in the entire surrounding area of the element-formation region Ra to surround each element-formation region Ra. Therefore, two seal ring portions 40a appear in the cross-section of the dicing region Rd. The seal ring portion 40a is a portion of the seal ring 40 and may be formed of conductive metal, such as tungsten, for example.

Next, a trench TR60 is formed in the first interlayer dielectric film 30 by lithography and etching. The trench TR60 is provided in the entire surrounding area of the element-formation region Ra along an outer side surface of the seal ring portion 40a. The trench TR60 is provided between the two seal ring portions 40a adjacent to each other in the dicing region Rd. Each trench TR60 is formed in the vicinity of the seal ring portion 40a.

Subsequently, a conductive material is filled into the trench TR60 and a trench TR40a. The conductive material may be a metal material, such as tungsten, titanium, or aluminum, that can form the first sidewall film 60. Accordingly, the first sidewall film 60 is formed in the trench TR60, and the seal ring portion 40a is formed in the trench TR40a. The first sidewall film 60 is formed in the first interlayer dielectric film 30 in the dicing region Rd along a periphery of each of the element-formation regions Ra.

In a case of using a silicon nitride film as the material of the first sidewall film 60, the trench TR60 and the first sidewall film 60 are formed separately from the trench TR40a and the seal ring portion 40a. In this case, any conductive material can be used for the seal ring portion 40a.

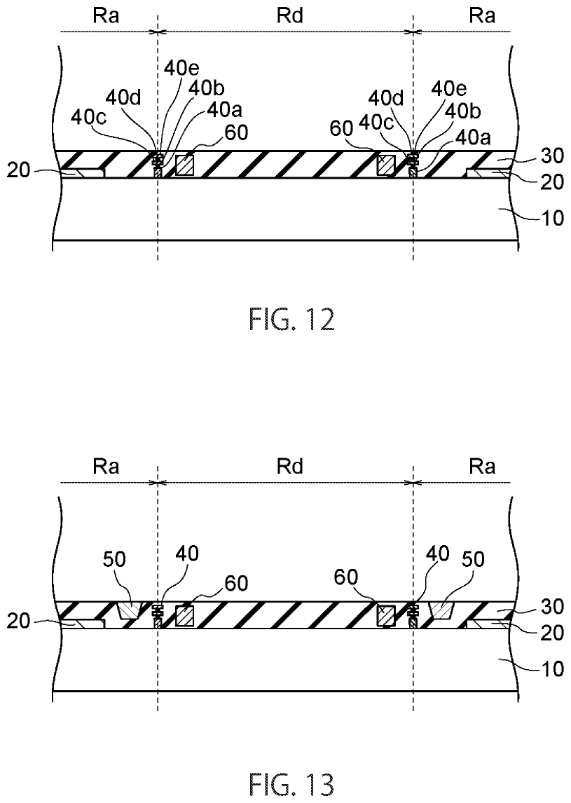

Similarly to formation of the seal ring portions 140b to 140e, deposition of the material of the first interlayer dielectric film 30, formation of a trench, and filling of the trench with a conductive material are repeated to form seal ring portions 40b to 40e in the first interlayer dielectric film 30, as illustrated in FIG. 12. The seal ring portions 40a to 40e can be formed simultaneously in a process of forming the semiconductor element 20 or a wiring layer above the semiconductor element 20. The seal ring portions 40a to 40e are referred to as the seal ring 40 in the following description. The seal ring 40 in FIG. 1 is illustrated by simplifying the seal ring 40 illustrated in FIG. 12.

Next, the material of the first interlayer dielectric film 30 is further deposited, and thereafter the bonding pad 50 is formed in the first interlayer dielectric film 30. The bonding pad 50 is formed between the seal ring 40 and the semiconductor element 20 in the element-formation region Ra. A surface of the bonding pad 50 is substantially flush with a surface of the first interlayer dielectric film 30 and is exposed from the first interlayer dielectric film 30. In this manner, the semiconductor element 20 such as a CMOS is formed on the semiconductor substrate 10.

### (Bonding Process)

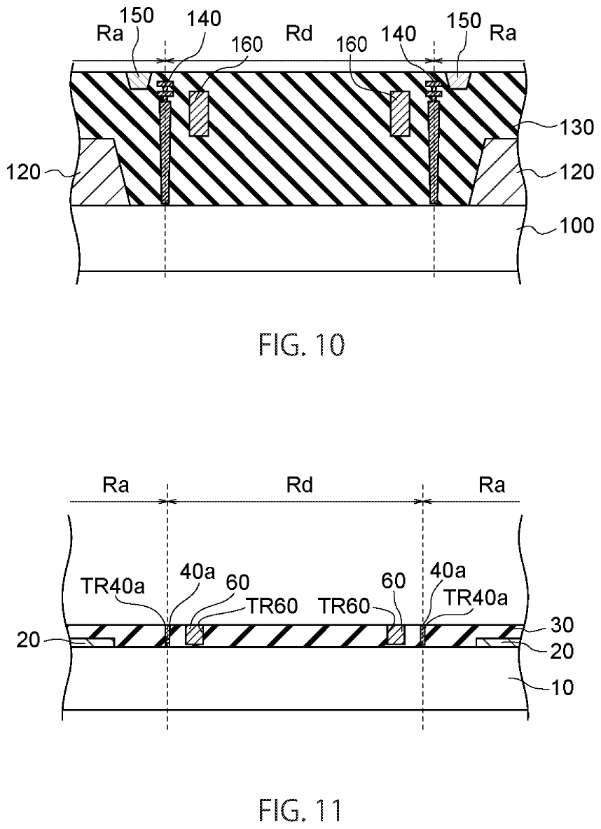

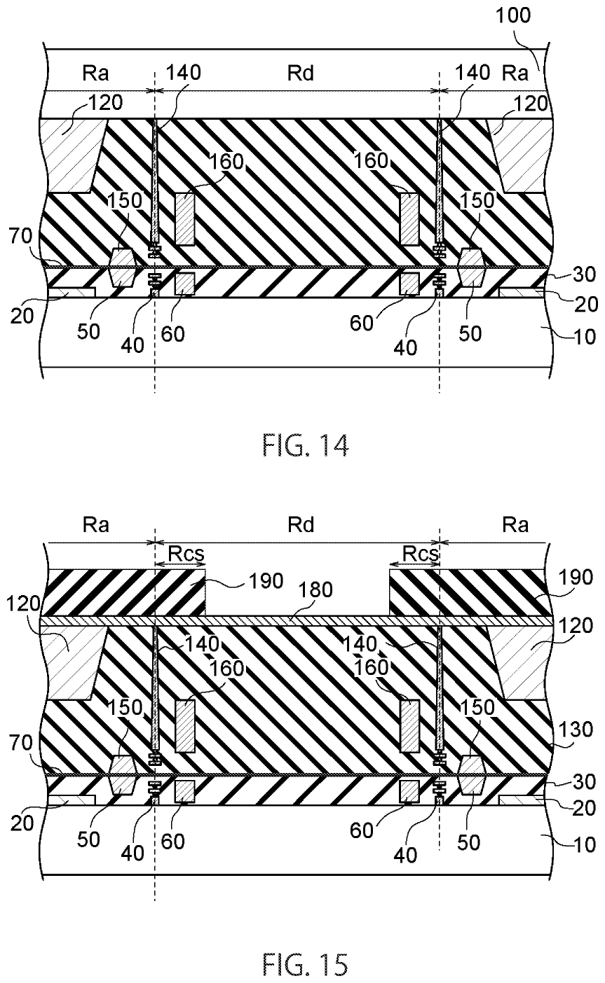

Next, as illustrated in FIG. 14, the semiconductor substrate 10 on the memory chip Cm side in FIG. 10 and the semiconductor substrate 100 on the controller chip Cc side in FIG. 13 are bonded to each other. At this time, both the semiconductor substrates 10 and 100 are still in a state of a semiconductor wafer. The semiconductor substrates 10 and 100 are bonded to each other in such a manner that an element-formation surface of the semiconductor substrate 10 and an element-formation surface of the semiconductor substrate 100 are opposed to each other. Further, the semiconductor substrates 10 and 100 are bonded to each other in such a manner that the element-formation region Ra of the semiconductor substrate 10 and the element-formation region Ra of the semiconductor substrate 100 correspond to each other and the dicing region Rd of the semiconductor substrate 10 and the dicing region Rd of the semiconductor substrate 100 correspond to each other. Accordingly, the bonding pad 50 and the bonding pad 150 are in contact with each other at the bonding surface 70. Further, the position of the seal ring 40 and the position of the seal ring 140 correspond to each other, and the position of the first sidewall film 60 and the position of the first sidewall film 160 also correspond to each other. Therefore, when the semiconductor substrates 10 and 100 are viewed from above surfaces thereof, the position of the bonding pad 50 and the position of the bonding pad 150 are substantially coincident with each other, the position of the seal ring 40 and the position of the seal ring 140 are substantially coincident with each other, and the position of the first sidewall film 60 and the position of the first sidewall film 160 are substantially coincident with each other. In addition, although not illustrated, an electrode pad of the controller chip Cc and an electrode pad of the memory chip Cm are brought into electrical contact with each other by bonding, so that the semiconductor element 20 is electrically connected to the memory cell array 120 and the memory cell array 120 becomes controllable. Here, at the bonding surface 70, silicon oxide films respectively included in the first interlayer dielectric film 30 and the second interlayer dielectric film 130 are in direct contact with each other.

Subsequently, the semiconductor substrate 100 is removed to expose the second interlayer dielectric film 130, and then the metal film 180 is formed on the second interlayer dielectric film 130. Conductive metal, such as copper, aluminum, or titanium is used for the metal film 180, for example.

Subsequently, the protection film 190 is formed on the metal film 180. For example, an insulating film, such as a polyimide film, is used as the protection film 190. Next, the protection film 190 is processed by lithography and etching. With this processing, the structure illustrated in FIG. 15 is obtained. A region of the dicing region Rd, covered by the protection film 190, is a crack stopper region Rcs. The first sidewall films 60 and 160 are provided in the crack stopper region Rcs, and suppress expansion of a crack beyond the seal rings 40 and 140 toward the element-formation region Ra in a dicing process that uses laser light or a blade. A case where the first sidewall films 60 and 160 have substantially the same configurations as the seal rings 40 and 140 is illustrated in FIG. 28.

### (Dicing Process)

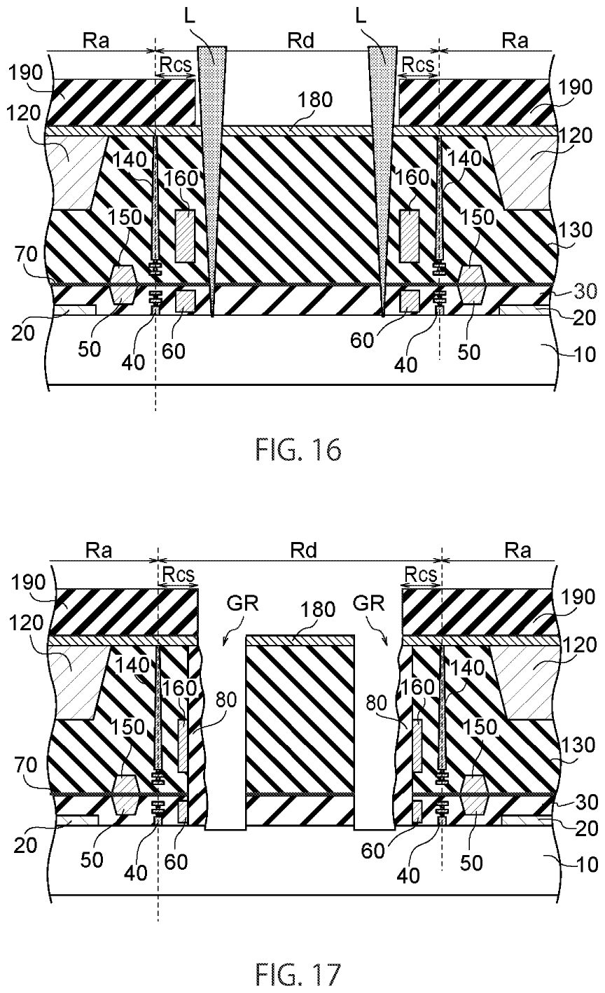

Next, laser light L is irradiated onto the first sidewall films 60 and 160 served as light absorption films in the dicing region Rd or a portion in the vicinity thereof, as illustrated in FIG. 16. Laser light is irradiated onto the first sidewall films 60 and 160 served as light absorption films along an outer periphery of each of the element-formation regions Ra to form a groove GR in the first interlayer dielectric film 30 and the second interlayer dielectric film 130. The first sidewall films 60 and 160 are formed of materials that can absorb the laser light L more easily than the first interlayer dielectric film 30 and the second interlayer dielectric film 130. Therefore, the first sidewall films 60 and 160 absorb the laser light L and generate heat, thereby melting the first and second interlayer dielectric films 30 and 130 therearound. At least portions of the first interlayer dielectric film 30 and the second interlayer dielectric film 130 are vaporized by ablation and are removed. Accordingly, as illustrated in FIG. 17, the two grooves GR are formed on both sides of the dicing region Rd, and the first interlayer dielectric film 30 and the second interlayer dielectric film 130 are at least partly melted and melted portions are formed. At this time, portions of the first interlayer dielectric film 30 and the second interlayer dielectric film 130, which have not been melted, are referred to as unmelted portions.

At least portions of the first sidewall films 60 and 160 absorb the laser light L and melt, thereby becoming melted portions. Portions of the first sidewall films 60 and 160, which have not melted, are referred to as unmelted portions. At this time, the melted portions are welded to the unmelted portions of the first sidewall films 60 and 160 and the side surfaces of the first interlayer dielectric film 30 and the second interlayer dielectric film 130, and become solidification portions. The unmelted portions of the first sidewall films 60 and 160 become unmelted portions.

The solidification portions of the first and second solidification portions 30, 130 and the solidification portions of the first sidewall films 60, 160 are welded and solidified to the unmelted portions of the first and second solidification portions 30, 130 and to the unmelted portions of the first sidewall films 60 and 160 to form the second sidewall film 80. That is, the solidification portions of the first and second solidification portions 30, 130 and the solidification portions of the first sidewall films 60, 160 are welded and solidified to side surfaces of the grooves GR to form the second sidewall film 80.

Accordingly, the second sidewall film 80 contains the compositions of the first and second solidification portions 30, 130 and the first sidewall films 60, 160.

The grooves GR are provided in the entire surrounding area of the element-formation region Ra to surround each element-formation region Ra, similarly to the seal rings 40 and 140. Therefore, the grooves GR are formed on both sides of the dicing region Rd in the cross-section of the dicing region Rd along a direction substantially perpendicular to an extending direction of the dicing region Rd, as illustrated in FIG. 17.

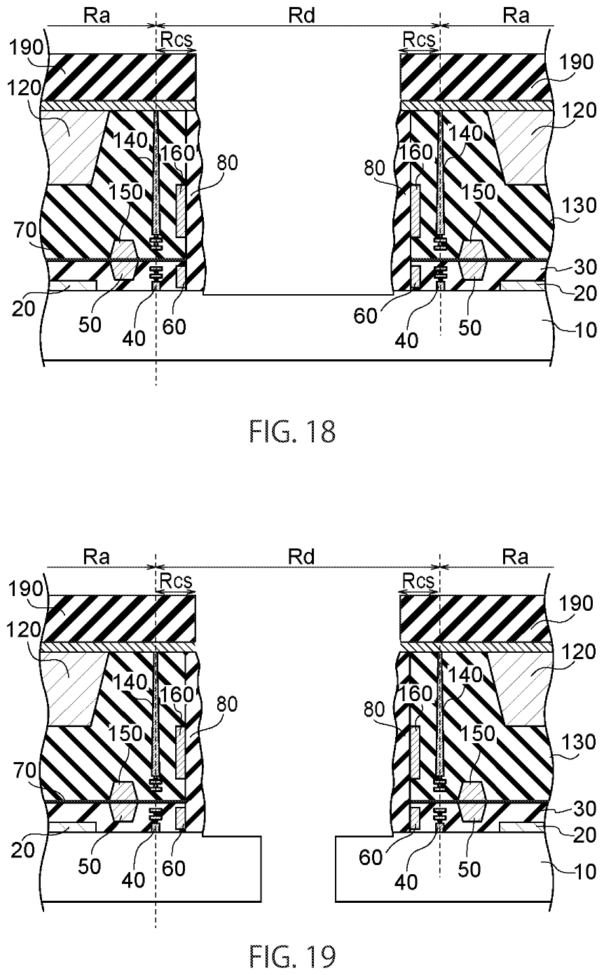

Subsequently, the metal film 180, the first interlayer dielectric film 30, and the second interlayer dielectric film 130 between the adjacent grooves GR in the dicing region Rd are removed by laser light. Accordingly, the structure illustrated in FIG. 18 is obtained.

Subsequently, the semiconductor substrate 10 in the dicing region Rd is cut with a blade (not illustrated). Accordingly, the adjacent element-formation regions Ra are cut to be diced into semiconductor chips, as illustrated in FIG. 19. In this manner, the semiconductor device 1 illustrated in FIGS. 1, 2A, and 2B is completed.

As described above, according to the first embodiment, the first sidewall films 60 and 160 of each of which an absorption coefficient for laser light is relatively large are formed in the dicing region Rd outside the seal rings 40 and 140. In a dicing process, the first sidewall films 60 and 160 absorb the laser light and function as heat sources, and melt the first interlayer dielectric film 30 and the second interlayer dielectric film 130. Accordingly, the materials of the first interlayer dielectric film 30 and the second interlayer dielectric film 130 are welded to side surfaces of the first interlayer dielectric film 30 and the second interlayer dielectric film 130 and side surfaces of the first sidewall films 60 and 160 as the second sidewall film 80. Further, the first sidewall films 60 and 160 themselves also melt by absorbing the laser light, thereby being welded to the side surfaces of the first interlayer dielectric film 30 and the second interlayer dielectric film 130. Accordingly, the second sidewall film 80 and the first sidewall films 60 and 160 can suppress delamination of the first interlayer dielectric film 30 and the second interlayer dielectric film 130 towards the element-formation region Ra.

Further, the second sidewall film 80 also covers an end of the bonding surface 70 and is welded to it. Accordingly, it is possible to suppress delamination between the memory chip Cm and the controller chip Cc at the bonding surface 70.

### Second Embodiment

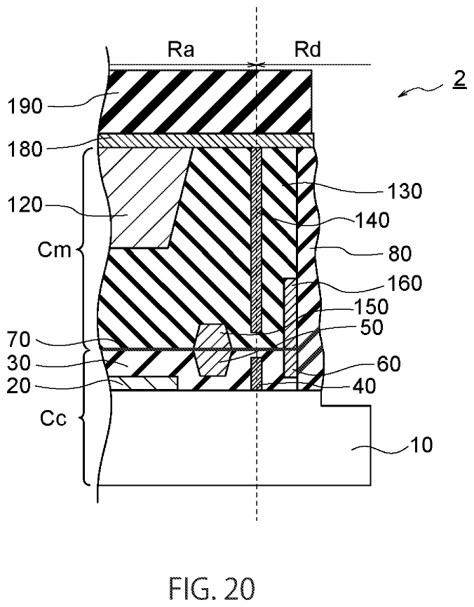

FIG. 20 is a cross-sectional view illustrating a configuration example of a semiconductor device according to a second embodiment. A semiconductor device 2 according to the second embodiment is different from that according to the first embodiment in that the first sidewall films 60 and 160 are in contact with each other at the bonding surface 70. Because of contact between the first sidewall films 60 and 160 at the bonding surface 70, the first sidewall films 60 and 160 cover an end of the bonding surface 70. Accordingly, delamination at the bonding surface 70 can be suppressed more surely. The rest of the structure of the second embodiment may be identical to corresponding one of the first embodiment.

Further, in the second embodiment, it suffices that the first sidewall films 60 and 160 are formed immediately before or immediately after a formation process of the bonding pads 50 and 150, respectively. As a result, surfaces of the first sidewall films 60 and 160 can be flush with surfaces of the first interlayer dielectric film 30 and the second interlayer dielectric film 130, respectively, similarly to the bonding pads 50 and 150.

Even if the materials of the first interlayer dielectric film 30 and the second interlayer dielectric film 130 are provided on the first sidewall films 60 and 160 to some extent, laser light melts the first interlayer dielectric film 30 and the second interlayer dielectric film 130 in a dicing process, and therefore the first sidewall film 60 and the first sidewall film 160 can come in contact with each other at the bonding surface 70. For example, the material of the first interlayer dielectric film 30 or the material of the second interlayer dielectric film 130 may be left on the first sidewall film 60 or 160 with a thickness of about 1.5 μm. Further, in a case where the first sidewall films 60 and 160 have the same configurations as the seal rings 40 and 140, respectively, it suffices to further form the material of a first sidewall film on the first sidewall films 60 and 160 immediately before or immediately after a formation process of the bonding pads 50 and 150, respectively. Accordingly, it is possible to allow the first sidewall films 60 and 160 to be in contact with each other and be welded to each other at an end of the bonding surface 70.

Other manufacturing processes of the second embodiment may be identical to corresponding ones of the first embodiment. Accordingly, the second embodiment can obtain effects identical to those of the first embodiment.

### Third Embodiment

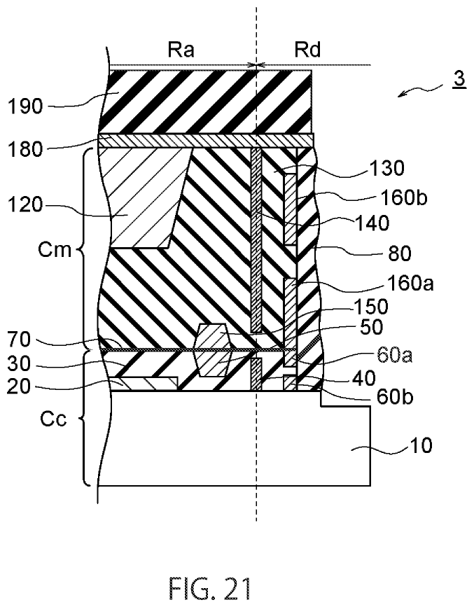

FIG. 21 is a cross-sectional view illustrating a configuration example of a semiconductor device according to a third embodiment. According to the third embodiment, the first sidewall films 60 and 160 are each divided into a plurality of pieces in a direction substantially perpendicular to surfaces of the semiconductor substrates 10 and 100. For example, the first sidewall film 60 is divided into first sidewall films 60a and 60b, and the first sidewall film 160 is divided into first sidewall films 160a and 160b. Accordingly, heat sources that are caused to generate heat by laser light are increased, so that the first interlayer dielectric film 30, the second interlayer dielectric film 130, and the first sidewall films 60 and 160 can be melted easily and efficiently over a wide range in the above-described perpendicular direction and can be surely welded to side surfaces of the first interlayer dielectric film 30 and the second interlayer dielectric film 130 and a side surface of the bonding surface 70. The rest of the structure of the third embodiment may be identical to corresponding one of the first or second embodiment.

It suffices that the first sidewall films 60 and 160 are formed by any process when the first interlayer dielectric film 30 and the second interlayer dielectric film 130 are stacked. For example, after the first sidewall film 160 is formed in the process illustrated in FIG. 6, a first sidewall film is formed simultaneously with any one of the seal ring portions 140c to 140e illustrated in FIG. 9 in a formation process of any one of the seal ring portions 140c to 140e. Accordingly, the plural first sidewall films 160 (for example, 160a and 160b) can be formed at corresponding positions in the same layer as any of the seal ring portions 140c to 140e. Also regarding the first sidewall films 60, it suffices to form them in an identical manner.

Other manufacturing processes of the third embodiment may be identical to corresponding ones of the first or second embodiment. Accordingly, the third embodiment can obtain effects identical to those of the first or second embodiment.

### Fourth Embodiment

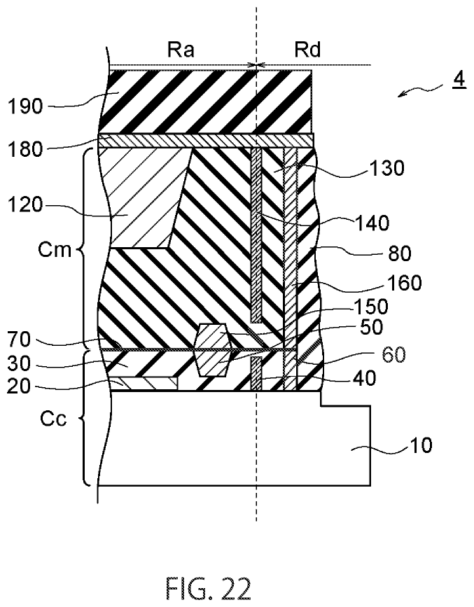

FIG. 22 is a cross-sectional view illustrating a configuration example of a semiconductor device according to a fourth embodiment. A semiconductor device 4 according to the fourth embodiment is different from that according to the first embodiment in that the first sidewall films 60 and 160 cover the entire side surfaces of the first interlayer dielectric film 30 and the second interlayer dielectric film 130. The first sidewall film 60 covers the side surface of the first interlayer dielectric film 30 from a top surface of the semiconductor substrate 10 to a top surface of the first interlayer dielectric film 30, and the first sidewall film 160 covers the side surface of the second interlayer dielectric film 130 from a top surface of the metal film 180 to a top surface of the second interlayer dielectric film 130. Accordingly, the first sidewall films 60 and 160 can be surely welded to the side surfaces of the first interlayer dielectric film 30 and the second interlayer dielectric film 130 and an end of the bonding surface 70. The rest of the structure of the fourth embodiment may be identical to corresponding one of the first embodiment. Accordingly, the fourth embodiment can obtain effects identical to those of the first embodiment.

### Fifth Embodiment

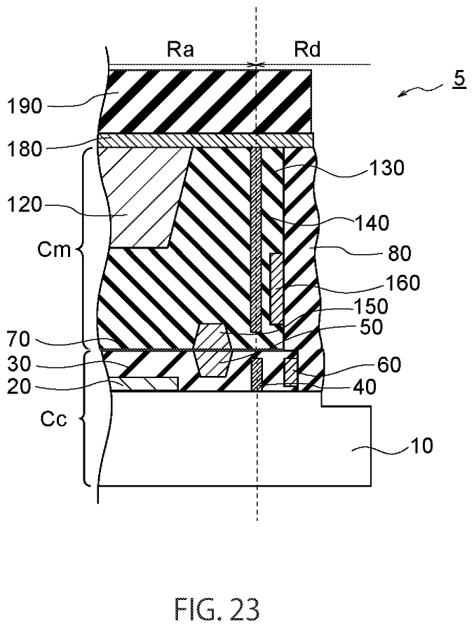

FIG. 23 is a cross-sectional view illustrating a configuration example of a semiconductor device according to a fifth embodiment. A semiconductor device 5 according to the fifth embodiment is different from that according to the first embodiment in that the first sidewall films 60 and 160 are shifted from each other in a direction substantially parallel to a surface of the semiconductor substrate 10. That is, the positions of the first sidewall films 60 and 160 are not coincident with each other (do not overlap) when being viewed from above the surface of the semiconductor substrate 10. The rest of the structure of the fifth embodiment may be identical to corresponding one of the first embodiment. Even in the structure of the fifth embodiment, effects identical to those of the first embodiment can be obtained.

### Sixth Embodiment

As in the embodiments described above, the length, the width, and the number of the first sidewall films 60 and 160 are not particularly limited to any specific ones.

However, distances D1 and D2 between the seal rings 40 and 140 and the first sidewall films 60 and 160 illustrated in FIG. 1 are set by taking variation of an irradiated position of laser light or an influence of heat on the seal rings 40 and 140 into consideration. For example, it is assumed that the variation of the irradiated position of the laser light is about 4 μm and the first interlayer dielectric film 30 and the second interlayer dielectric film 130 within a range of about 5 μm from the first sidewall films 60 and 160 are melted. That is, it is assumed that a heat affected zone (HAZ) by the laser light L is about 5 μm. In this case, if the distances D1 and D2 are less than about 9 μm, there is a possibility that, when the irradiated position of laser light is shifted toward the seal rings 40 and 140, heat from the first sidewall films 60 and 160 is transferred to the seal rings 40 and 140 to melt the seal rings 40 and 140. Meanwhile, if the distances D1 and D2 are about 9 μm or more, heat from the first sidewall films 60 and 160 cannot be sufficiently transferred to the seal rings 40 and 140 even when the irradiated position of laser light is shifted toward the seal rings 40 and 140. Therefore, it is possible to suppress melting of the seal rings 40 and 140.

The rest of the structure of the sixth embodiment may be identical to corresponding one of the first embodiment. Accordingly, the sixth embodiment can also obtain effects identical to those of the first embodiment.

### Seventh Embodiment

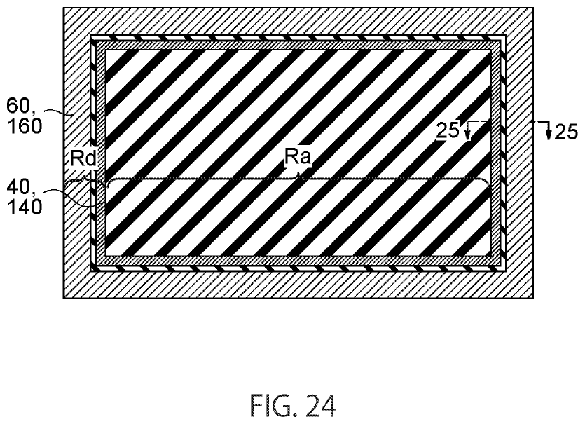

FIG. 24 is a plan view illustrating a configuration example of a semiconductor device according to a seventh embodiment. The widths (the widths in a direction substantially parallel to a surface of the semiconductor substrate 10) of the first sidewall films 60 and 160 illustrated in FIG. 24 are wider than those in the first embodiment. The first sidewall films 60 and 160 are exposed from a side surface of the second sidewall film 80 and are provided in the entire outer edge of a semiconductor chip. The rest of the structure of the seventh embodiment may be identical to corresponding one of the first embodiment.

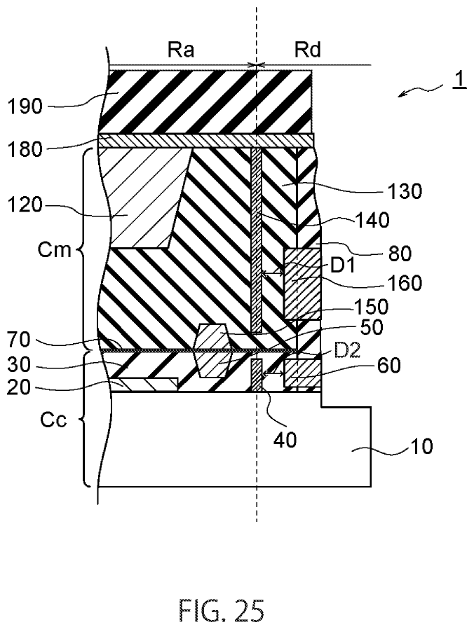

FIG. 25 illustrates a cross-section along a line 25-25 in FIG. 24. As illustrated in FIG. 25, the first sidewall films 60 and 160 are provided from positions away from the seal rings 40 and 140 by the distances D1 and D2 to an outer side surface of the second sidewall film 80, respectively. In this manner, the first sidewall films 60 and 160 may be uncovered by the second sidewall film 80. Also in this case, the first sidewall films 60 and 160 are welded to side surfaces of the first interlayer dielectric film 30 and the second interlayer dielectric film 130 and therefore have an effect of suppressing delamination of the first interlayer dielectric film 30 and the second interlayer dielectric film 130. FIG. 25 illustrates a cross-section in a case where the seventh embodiment is applied to the first embodiment. However, the seventh embodiment may be applied to any of the second to sixth embodiments. That is, the length and the number of the first sidewall films 60 and 160 are not particularly limited to any specific ones. Accordingly, the seventh embodiment can obtain effects of any one of the first to sixth embodiments.

Further, although not illustrated, the widths (the widths in the direction substantially parallel to the surface of the semiconductor substrate 10) of the intermittent first sidewall films 60 and 160 illustrated in FIGS. 2A and 2B may be changed in an identical manner to those in the seventh embodiment. Furthermore, although not illustrated, the widths of the first sidewall films 60 and 160 may be narrower than those in the first embodiment.

### Eighth Embodiment

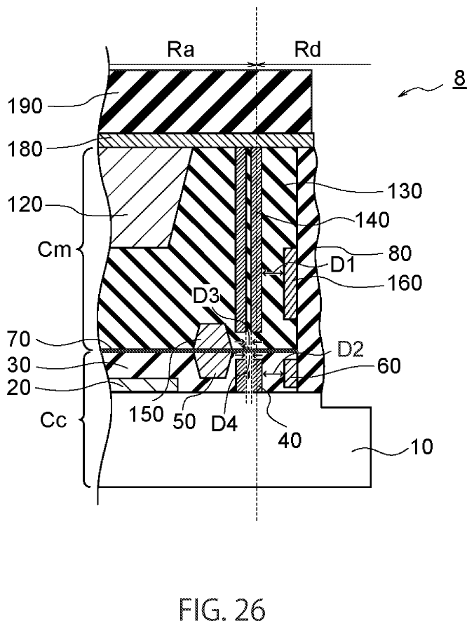

FIG. 26 is a cross-sectional view illustrating a configuration example of a semiconductor device according to an eighth embodiment. A semiconductor device 8 according to the eighth embodiment is different from the semiconductor device according to the first embodiment in that the plural seal rings 40 and the plural seal rings 140 are provided. The seal rings 40 have mutually the same configuration and the same function. The seal rings 140 have mutually the same configuration and the same function. The rest of the structure of the eighth embodiment may be identical to corresponding one of the first embodiment. Accordingly, the eighth embodiment can also obtain effects identical to those of the first embodiment.

A distance D3 between the adjacent seal rings 140 is preferably narrower than the distance D1. Further, a distance D4 between the adjacent seal rings 40 is preferably narrower than the distance D2. That is, the first sidewall film 60 is provided outside the seal rings 40 with the distance D1 larger than D3 as a first distance. The first sidewall film 160 is provided outside the seal rings 140 with the distance D2 larger than D4 as the first distance. The distances D3 and D4 can be narrower than D1 and D2, respectively, for downscaling the semiconductor device 8. Meanwhile, it is necessary to enlarge the distances D1 and D2 to some extent in order to prevent heat from the first sidewall films 60 and 160 from affecting the seal rings 40 and 140. It is therefore preferable that D1>D3 and D2>D4 are established.

The number of each of the seal rings 40 and 140 arranged in parallel may be three or more. The eighth embodiment may be applied to any of the second to seventh embodiments. Accordingly, the eighth embodiment can obtain effects of any one of the first to seventh embodiments.

In a case of applying the eighth embodiment to the sixth embodiment, when it is assumed that the first distance D3 is about 1 μm, it is preferable that a distance between an outermost one of the seal rings 140 and the first sidewall film 160 is 9 μm or more. When it is assumed that the first distance D4 is about 1 μm, it is preferable that a distance between an outermost one of the seal rings 40 and the first sidewall film 60 is 9 μm or more.

### Ninth Embodiment

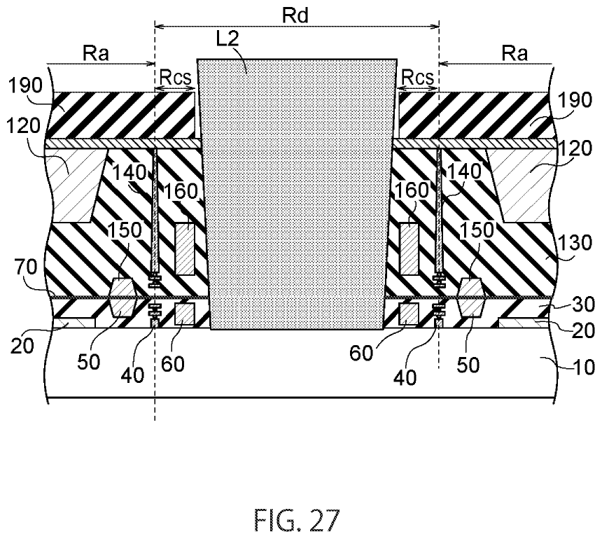

FIG. 27 is a cross-sectional view illustrating a manufacturing method of a semiconductor device according to a ninth embodiment. In the first embodiment, a plurality of elements of the laser light L having relatively narrow widths are irradiated onto the first sidewall films 60 and 160 in the dicing region Rd or a portion in the vicinity thereof in a dicing process. Meanwhile, in a dicing process according to the ninth embodiment, laser light L2 having relatively wide width is irradiated onto the entire dicing region Rd between the adjacent first sidewall films 60 and between the adjacent first sidewall films 160.

Accordingly, an identical structure to that in FIG. 18 can be obtained only by irradiating the laser light L2 once in each dicing region Rd. Other processes of the ninth embodiment may be identical to a process of any one of the first to eighth embodiments. Accordingly, the ninth embodiment can also obtain effects identical to those of any one of the first to eighth embodiments.

### Tenth Embodiment

FIG. 28 is a cross-sectional view illustrating a manufacturing method of a semiconductor device according to a tenth embodiment. In the tenth embodiment, the first sidewall films 60 and 160 have substantially the same configurations as the seal rings 40 and 140 and are formed at substantially the same levels as the seal rings 40 and 140, respectively. Accordingly, it is possible to suppress complication and elongation of a manufacturing process of the semiconductor device 1. Other processes of the tenth embodiment may be identical to a process of any one of the first to ninth embodiments. Accordingly, the tenth embodiment can also obtain effects identical to those of any one of the first to ninth embodiments.

In the embodiments described above, about 355-nm ultraviolet light is used as laser light. Even in a case of using visible or infrared laser light having a wavelength of 400 nm or more, the effects of the embodiments described above can be obtained by setting absorptances of the first sidewall films 60 and 160 at that wavelength to be larger than those of the first interlayer dielectric film 30 and the second interlayer dielectric film 130.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

1. A semiconductor device comprising:
a semiconductor substrate;
a semiconductor element provided on the semiconductor substrate;
a first insulation film configured to cover the semiconductor element; and
a first sidewall film provided on a side part of the first insulation film, of which an absorption coefficient for ultraviolet light is larger than that of the first insulation film.

2. The device of claim 1, wherein the first sidewall film includes a silicon nitride film.

3. The device of claim 1, wherein the first sidewall film includes a metal film.

4. The device of claim 3, wherein the first sidewall film contains at least one of tungsten, titanium, and aluminum.

5. The device of claim 1, further comprising a second sidewall film configured to cover an outer side of the first sidewall film.

6. The device of claim 5, wherein the first insulation film includes a first interlayer dielectric film and a second interlayer dielectric film provided above the first interlayer dielectric film, and
the first sidewall film or the second sidewall film is in direct contact with an interface between the first interlayer dielectric film and the second interlayer dielectric film.

7. The device of claim 6, wherein the semiconductor element includes a first semiconductor circuit that is provided on the semiconductor substrate and is covered by the first interlayer dielectric film, and a second semiconductor circuit that is provided above the first semiconductor circuit and is covered by the second interlayer dielectric film.

8. The device of claim 7, wherein the first semiconductor circuit is a CMOS circuit and the second semiconductor circuit is a memory cell, or the first semiconductor circuit is a memory cell and the second semiconductor circuit is a CMOS circuit.

9. The device of claim 6, wherein a conductor vertically crosses the interface along a direction perpendicular to the semiconductor substrate.

10. The device of claim 9, wherein the conductor contains copper.

11. The device of claim 6, wherein the interface is a surface at which a silicon oxide film included in the first interlayer dielectric film and a silicon oxide film included in the second interlayer dielectric film are in contact with each other.

12. The device of claim 1, further comprising a seal ring configured to surround the semiconductor element, wherein
the first sidewall film is provided outside the seal ring and contains a same material as the seal ring.

13. The device of claim 1, further comprising a plurality of seal rings surrounding the semiconductor element and arranged with a first distance in a direction substantially parallel to a top surface of the semiconductor substrate, wherein
the first sidewall film is provided outside the seal rings with a distance larger than the first distance.

14. The device of claim 13, wherein a distance between an outermost one of the seal rings and the first sidewall film is 9 μm or more.

15. The device of claim 1, wherein the first sidewall film is provided on an entire side surface of the first insulation film.

16. A manufacturing method of a semiconductor device, comprising, for a semiconductor substrate that includes a plurality of semiconductor elements provided thereon, a light absorption film covering the semiconductor substrate, and a first embedding film provided in the first insulation film, having a larger absorption coefficient for ultraviolet light than that of the first insulation film, and formed in a surrounding area of the semiconductor elements when being viewed from a direction perpendicular to the semiconductor substrate:
irradiating laser light along a periphery of a plurality of semiconductor elements to form a groove in the first insulation film, and forming first sidewall films including at least a part of the light absorption film on a side surface of the first insulation film; and
cutting between the first sidewall films with a blade.

17. The method of claim 16, wherein
irradiation of the ultraviolet laser light forms a melted portion in which at least a portion of the light absorption film is melted, and
a second sidewall film, which is the melted portion welded and solidified, is formed on side surface of the first sidewall film.

18. The method of claim 17, wherein
irradiation of the ultraviolet laser light forms a melted portion in which at least a portion of the first insulation film is melted, and
a second sidewall film, which is the melted portion welded and solidified, is formed on side surface of the first sidewall film.

19. The method of claim 18, wherein
the first insulation film includes a first interlayer dielectric film and a second interlayer dielectric film provided above the first interlayer dielectric film, the semiconductor element includes a first semiconductor circuit that is provided on the semiconductor substrate and is covered by the first interlayer dielectric film and a second semiconductor circuit that is provided above the first semiconductor circuit,
irradiation of the ultraviolet laser light forms a melted portion in which at least a portion of the first sidewall film and/or the light absorption film is melted, and
a second sidewall film, which is the melted portion welded and solidified, is formed on an edge part of the bonding surface between the first and second interlayer dielectric films the side surface of the first sidewall film.

20. The method of claim 19, wherein
the first semiconductor circuit is a CMOS circuit and the second semiconductor circuit is a memory cell, or the first semiconductor circuit is a memory cell and the second semiconductor circuit is a CMOS circuit,
the interface is a surface at which a silicon oxide film included in the first interlayer dielectric film and a silicon oxide film included in the second interlayer dielectric film are in contact with each other, and
a conductor containing copper crosses the interface along a direction perpendicular to the semiconductor substrate.
